(19) United States
(12) Patent Application Publication
(10) Pub. No.: US 2025/0143013 A1
(43) Pub. Date: May 1, 2025

(54) METHOD FOR MANUFACTURING HIGH-RELIABILITY LIGHT SOURCE MODULE

(71) Applicant: Xiamen PVTECH Co., Ltd., Xiamen (CN)

(72) Inventors: FUXING LU, Xiamen, Fujian (CN); Huibao Luo, Xiamen (CN)

(73) Assignee: Xiamen PVTECH Co., Ltd., Xiamen (CN)

(21) Appl. No.: 18/774,944

(22) Filed: Jul. 17, 2024

(30) Foreign Application Priority Data
Oct. 30, 2023 (CN) 202311422214.3

(51) Int. Cl. H01L 33/00

(52) U.S. Cl. CPC H10H 20/01; H10H 20/0364

(57) ABSTRACT

A method for manufacturing high-reliability light source module includes the following steps: segmenting a circuit board into a first sub-circuit board and a second sub-circuit board; installing a plurality of light sources on the first sub-circuit board and the second sub-circuit board; placing the first and second sub-circuit boards on a section bar; splicing the first sub-circuit board with the second sub-circuit board, and aligning the positive and negative solder pads of the first sub-circuit board with the positive and negative solder pads of the second sub-circuit board; soldering the two ends of a first connector on the positive solder pad of the first sub-circuit board and the positive solder pad of the second sub-circuit board respectively; soldering one end of a second connector on the negative solder pad of the first sub-circuit board and the negative solder pad of the second sub-circuit board respectively.

### BACKGROUND OF THE INVENTION

### 1. Field of the Invention

The present invention relates to a method for manufacturing light source module, in particular to a method for manufacturing light-reliability light source module.

### 2. Description of the Prior Art

Currently available light sources used in tube lights are typically fixed on section bars, and the light source boards come in various lengths (e.g., 0.6 meters, 1.2 meters, 1.5 meters, 1.8 meters, 2.4 meters, etc.). Currently available light source boards are divided into two types: rigid printed circuit boards (RPCB) and flexible printed circuit boards (FPCB). FPCBs are usually segmented from large sheets of raw material. However, the length of most of currently available light source board are limited to 0.6 meters, 1.2 meters, and 1.5 meters, requiring expensive large-scale equipment for customized manufacturing of 1.8 meters or 2.4 meters light source boards. Additionally, most suppliers are unable to manufacture light source boards of these lengths. As a result, the manufacturing cost of 1.8 meters or 2.4 meters light source boards is significantly increased, thereby raising the manufacturing cost of tube lights.

### SUMMARY OF THE INVENTION

One embodiment of the present invention provides a method for manufacturing high-reliability light source module, which includes the following steps: segmenting a circuit board into a first sub-circuit board and a second sub-circuit board; installing a plurality of light sources on the first sub-circuit board and the second sub-circuit board; placing the first sub-circuit board and the second sub-circuit board on a section bar; splicing the first sub-circuit board with the second sub-circuit board, and aligning the positive solder pad and the negative solder pad of the first sub-circuit board with the positive solder pad and the negative solder pad of the second sub-circuit board; soldering one end of a first connector on the positive solder pad of the first sub-circuit board; soldering the other end of the first connector on the positive solder pad of the second sub-circuit board; soldering one end of a second connector on the negative solder pad of the first sub-circuit board; and soldering the other end of the second connector on the negative solder pad of the second sub-circuit board.

In one embodiment, the method further includes the following step: bending the first connector to form a first bending region including a plurality of first curved portions.

In one embodiment, the first curved portions are located above the positive solder pad of the first sub-circuit board or the positive solder pad of the second sub-circuit board.

In one embodiment, the method further includes the following step: bending the second connector to form a second bending region including a plurality of second curved portions.

In one embodiment, the second curved portions are located above the negative solder pad of the first sub-circuit board or the negative solder pad of the second sub-circuit board.

In one embodiment, the method further includes the following steps: bending the first connector to form a first protrusion portion; and bending the second connector to form a second protrusion portion, with the top end of the first protrusion portion facing the top end of the second protrusion portion.

In one embodiment, the method further includes the following step: cutting the circuit board to form a first groove and a second groove.

In one embodiment, the first groove is located between the first connector and the first side wall of the section bar.

In one embodiment, the second groove is located between the second connector and the second side wall of the section bar.

In one embodiment, the first connector and the second connector are solder strips, solder bars, or copper wires.

The method for manufacturing high-reliability light source module in accordance with the embodiments of the present invention may have the following advantages:
(1) In one embodiment of the present invention, the method for manufacturing high-reliability light source module includes the following steps: segmenting a circuit board into a first sub-circuit board and a second sub-circuit board; installing a plurality of light sources on the first sub-circuit board and the second sub-circuit board; placing the first sub-circuit board and the second sub-circuit board on a section bar; splicing the first sub-circuit board with the second sub-circuit board, and aligning the positive solder pad and the negative solder pad of the first sub-circuit board with the positive solder pad and the negative solder pad of the second sub-circuit board; soldering one end of a first connector on the positive solder pad of the first sub-circuit board; soldering the other end of the first connector on the positive solder pad of the second sub-circuit board; soldering one end of a second connector on the negative solder pad of the first sub-circuit board; and soldering the other end of the second connector on the negative solder pad of the second sub-circuit board. The aforementioned method enables the production of light source boards of different lengths (e.g., 0.6 meters, 1.2 meters, 1.5 meters, 1.8 meters, 2.4 meters, etc.) according to actual needs through simple steps without the need for large equipment. Thus, the method can significantly reduce the manufacturing cost of light source boards, such that the manufacturing cost of lighting devices can be greatly reduced to meet market demand.
(2) In one embodiment of the present invention, the first connector of the light source module has a first bending region with a plurality of first bending portions, and the first bending portions are stacked together. The second connector of the light source module has a second bending region with a plurality of second bending portions, and the second bending portions are stacked together. Through the aforementioned structural design, the first bending region and the second bending region can serve as buffering structures so as to effectively prevent the occurrence of fracture of the first connector and the second connector due to external stress or thermal expansion and contraction during transportation. Therefore, the reliability of the light source module can be greatly improved, such that the service life of lighting devices can be extended.
(3) In one embodiment of the present invention, the first connector of the light source module has a first protrusion portion, while the second connector of the light source module has a second protrusion portion, with the top end of the first protrusion portion facing the top end of the second protrusion portion. Through the aforementioned structural design, the first protrusion portion and the second protrusion portion can also serve as buffering structures with a view to effectively preventing the occurrence of fracture of the first connector and the second connector due to external stress or thermal expansion and contraction during transportation. Therefore, the reliability of the light source module can be greatly improved, such that the service life of lighting devices can be further extended.
(4) In one embodiment of the present invention, the circuit board of the light source module has a first groove and a second groove. The first groove is located between the first connector and the first side wall of the section bar, while the second groove is located between the second connector and the second side wall of the section bar. The aforementioned structural design can effectively increase the creepage distance between the solder pads of the light source module and the section bar. Therefore, the quality of the light source module can be effectively improved so as to meet actual requirements.
(5) In one embodiment of the present invention, the light sources of the light source module can be evenly distributed on the above sub-circuit boards. Therefore, through the aforementioned structural design, the light emitted by the light source module can be more uniform, thereby improving the overall efficiency of the lighting device. Consequently, the lighting device can provide users with a better user experience.

Further scope of applicability of the present application will become more apparent from the detailed description given hereinafter. However, it should be understood that the detailed description and specific examples, while indicating exemplary embodiments of the present invention, are given by way of illustration only, since various changes and modifications within the spirit and scope of the present invention will become apparent to those skilled in the art from this detailed description.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 is a first schematic view of a method for manufacturing high-reliability light source module in accordance with one embodiment of the present invention.

FIG. 2 is a second schematic view of the method for manufacturing high-reliability light source module in accordance with one embodiment of the present invention.

FIG. 3 is a third schematic view of the method for manufacturing high-reliability light source module in accordance with one embodiment of the present invention.

FIG. 4 is a fourth schematic view of the method for manufacturing high-reliability light source module in accordance with one embodiment of the present invention.

FIG. 5 is a fifth schematic view of the method for manufacturing high-reliability light source module in accordance with one embodiment of the present invention.

FIG. 6 is a sixth schematic view of the method for manufacturing high-reliability light source module in accordance with one embodiment of the present invention.

FIG. 7 is a seventh schematic view of the method for manufacturing high-reliability light source module in accordance with one embodiment of the present invention.

FIG. 8 is an eighth schematic view of the method for manufacturing high-reliability light source module in accordance with one embodiment of the present invention.

FIG. 9 is a ninth schematic view of the method for manufacturing high-reliability light source module in accordance with one embodiment of the present invention.

FIG. 10 is a flow chart of the method for manufacturing high-reliability light source module in accordance with one embodiment of the present invention.

FIG. 11 is a schematic view of a method for manufacturing high-reliability light source module in accordance with another embodiment of the present invention.

FIG. 12 is a flow chart of the method for manufacturing high-reliability light source module in accordance with another embodiment of the present invention.

FIG. 13 is a schematic view of a first connector in accordance with yet another embodiment of the present invention.

FIG. 14 is a schematic view of a second connector in accordance with yet another embodiment of the present invention.

FIG. 15 is a schematic view of a method for manufacturing high-reliability light source module in accordance with yet another embodiment of the present invention.

FIG. 16 is a first schematic view of a method for manufacturing high-reliability light source module in accordance with still another embodiment of the present invention.

FIG. 17 is a second schematic view of a method for manufacturing high-reliability light source module in accordance with still another embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

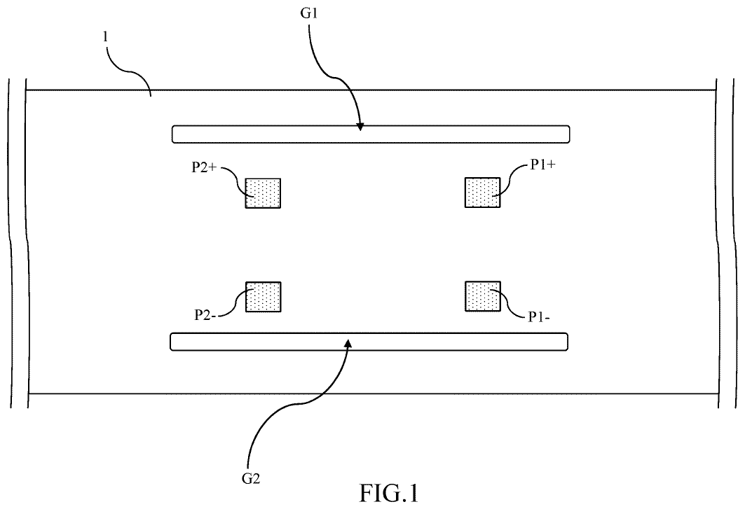

Please refer to FIG. 1, which is a first schematic view of a method for manufacturing high-reliability light source module in accordance with one embodiment of the present invention. As shown in FIG. 1, Firstly, a circuit board 1 is cut to form a first groove G1 and a second groove G2. In one embodiment, the circuit board 1 may be a flexible printed circuit board (FPCB). In another embodiment, the circuit board 1 may be a rigid printed circuit board (RPCB).

The embodiment just exemplifies the present invention and is not intended to limit the scope of the present invention; any equivalent modification and variation according to the spirit of the present invention is to be also included within the scope of the following claims and their equivalents.

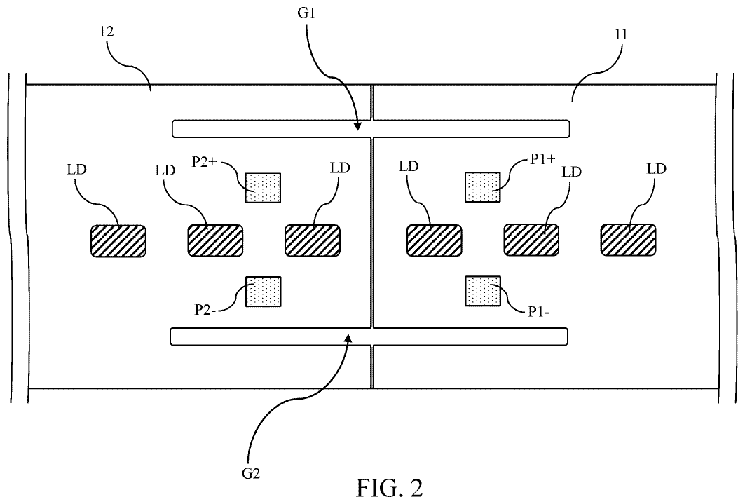

Please refer to FIG. 2, which is a second schematic view of the method for manufacturing high-reliability light source module in accordance with one embodiment of the present invention. As shown in FIG. 2, the circuit board 1 is segmented into a first sub-circuit board 11 and a second sub-circuit board 12. Subsequently, a plurality of light sources LD are installed on the first sub-circuit board 11 and the second sub-circuit board 12. In one embodiment, the aforementioned light sources LD may be light-emitting diodes (LEDs). In another embodiment, the aforementioned multiple light sources LD may be LED arrays. In one embodiment, the sizes of the first sub-circuit board 11 and the second sub-circuit board 12 may be equal. In another embodiment, the sizes of the first sub-circuit board 11 and the second sub-circuit board 12 may be unequal. In yet another embodiment, the circuit board 1 may be segmented into three or more sub-circuit boards.

The embodiment just exemplifies the present invention and is not intended to limit the scope of the present invention; any equivalent modification and variation according to the spirit of the present invention is to be also included within the scope of the following claims and their equivalents.

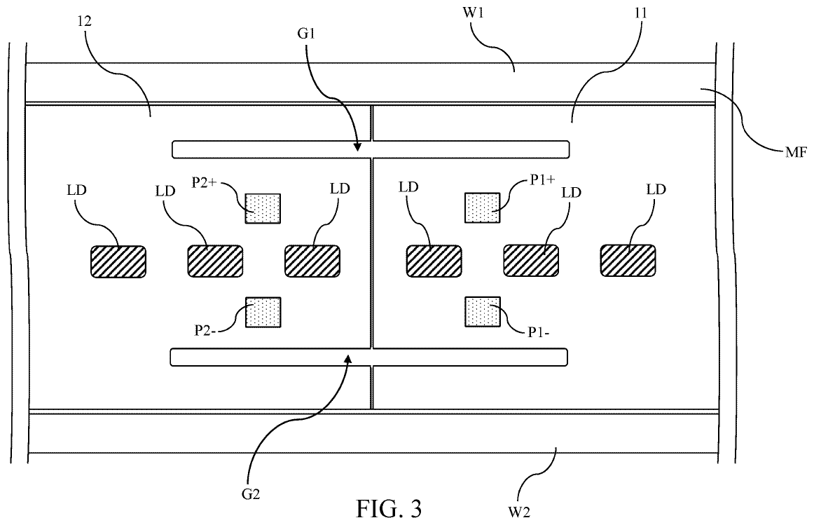

Please refer to FIG. 3, which is a third schematic view of the method for manufacturing high-reliability light source module in accordance with one embodiment of the present invention. As shown in FIG. 3, the first sub-circuit board 11 and the second sub-circuit board 12 are placed on the section bar MF. Subsequently, the first sub-circuit board 11 and the second sub-circuit board 12 are spliced with each other, and the positive solder pad P1+ and the negative solder pad P1− of the first sub-circuit board 11 are aligned with the positive solder pad P2+ and the negative solder pad P2− of the second sub-circuit board 12 respectively (the first sub-circuit board 11 and the second sub-circuit board 12 may be fixed to each other through riveting or similar methods). The positive solder pad P1+ and the negative solder pad P1− of the first sub-circuit board 11 can be located between two light sources LD (the two light sources LD are adjacent to each other, and one of which is adjacent to the second sub-circuit board 12). Similarly, the positive solder pad P2+ and the negative solder pad P2− of the second sub-circuit board 12 can be located between two light sources LD (the two light sources LD are adjacent to each other, and one of which is adjacent to the first sub-circuit board 11). In this way, the first sub-circuit board 11 and the second sub-circuit board 12 can form a complete light source board.

The embodiment just exemplifies the present invention and is not intended to limit the scope of the present invention; any equivalent modification and variation according to the spirit of the present invention is to be also included within the scope of the following claims and their equivalents.

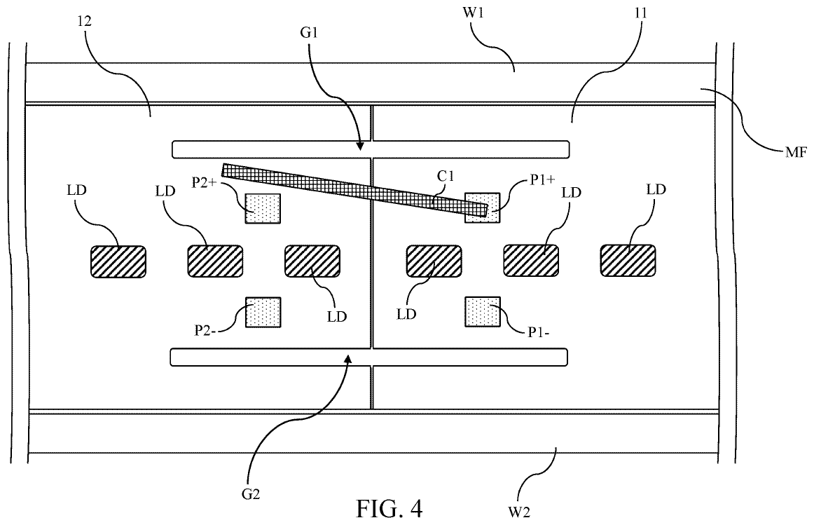

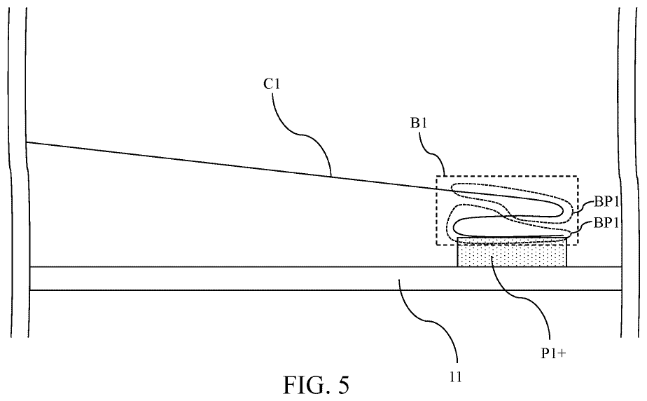

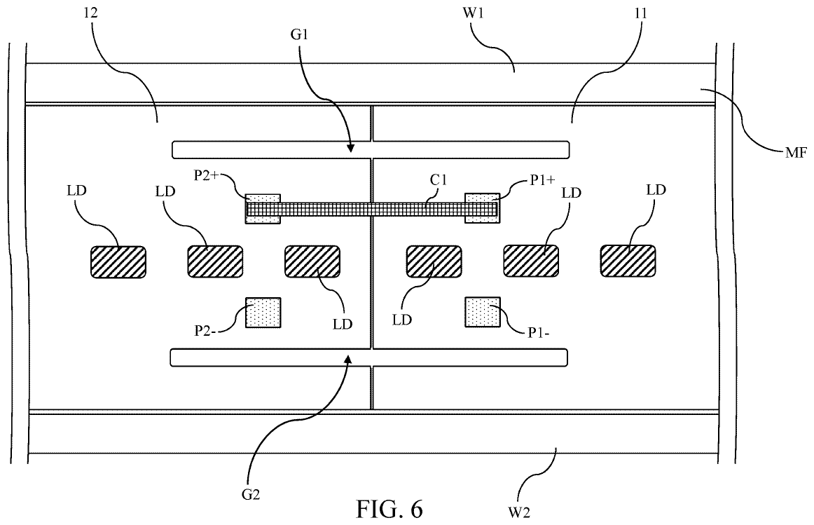

Please refer to FIG. 4 and FIG. 5. FIG. 5 is a fifth schematic view of the method for manufacturing high-reliability light source module in accordance with one embodiment of the present invention. FIG. 6 is a sixth schematic view of the method for manufacturing high-reliability light source module in accordance with one embodiment of the present invention. As shown in FIG. 4, one end of the first connector C1 is soldered on the positive solder pad P1+ of the first sub-circuit board 11. Then, As shown in FIG. 5, the first connector C1 is bent to form a first bending region B1. The first bending region B1 includes two first bending portions BP1, and the two first bending portions BP1 are stacked together to make the first bending region B1 be in S-shape. Thus, the first bending portions BP1 are located above the positive solder pad P1+ of the first sub-circuit board 11. In another embodiment, the first bending portions BP1 may also be located above the positive solder pad P2+ of the second sub-circuit board 12. In another embodiment, the first bending region B1 includes three or more first bending portions BP1, and the first bending portions BP1 are stacked together. In this embodiment, the first connector C1 is a solder strip. In another embodiment, the first connector C1 may also be a solder bar, copper wire, or similar component.

The embodiment just exemplifies the present invention and is not intended to limit the scope of the present invention; any equivalent modification and variation according to the spirit of the present invention is to be also included within the scope of the following claims and their equivalents.

Please refer to FIG. 6, which is a sixth schematic view of the method for manufacturing high-reliability light source module in accordance with one embodiment of the present invention. As shown in FIG. 6, the other end of the first connector C1 is then soldered on the positive solder pad P2+ of the second sub-circuit board 12. Thus, the first groove G1 is located between the first connector C1 and the first side wall W1 of the section bar MF.

The embodiment just exemplifies the present invention and is not intended to limit the scope of the present invention; any equivalent modification and variation according to the spirit of the present invention is to be also included within the scope of the following claims and their equivalents.

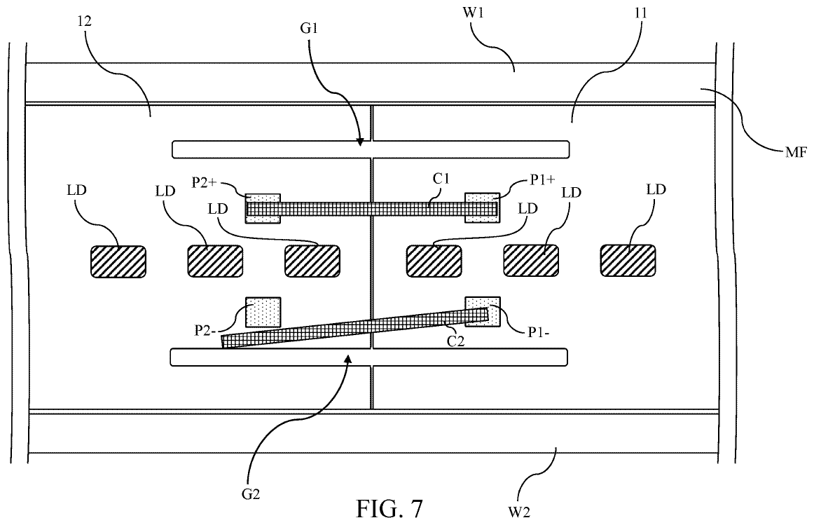

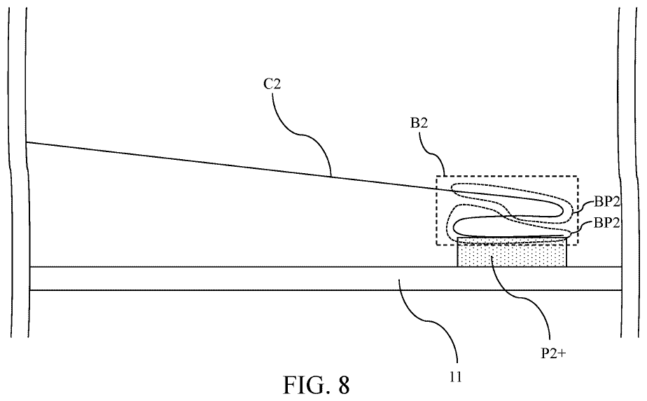

Please refer to FIG. 7 and FIG. 8. FIG. 7 is a seventh schematic view of the method for manufacturing high-reliability light source module in accordance with one embodiment of the present invention. FIG. 8 is an eighth schematic view of the method for manufacturing high-reliability light source module in accordance with one embodiment of the present invention. As shown in FIG. 7, similarly, one end of the second connector C2 is soldered on the negative solder pad P1− of the first sub-circuit board 11. As shown in FIG. 8, the second connector C2 is bent to form the second bending region B2. The second bending region B2 includes two second bending portions BP2, and the two second bending portions BP2 are stacked together to make the second bending region B2 be in S-shape. Thus, the second bending portions BP2 are located above the negative solder pad P1− of the first sub-circuit board 11. In another embodiment, the second bending portions BP2 may also be located above the negative solder pad P2− of the second sub-circuit board 12. In another embodiment, the second bending region B2 includes three or more second bending portions BP2, and the second bending portions BP2 are stacked together. In this embodiment, the second connector C1 is also a solder strip. In another embodiment, the second connector C2 may also be a solder bar, copper wire, or similar component.

The embodiment just exemplifies the present invention and is not intended to limit the scope of the present invention; any equivalent modification and variation according to the spirit of the present invention is to be also included within the scope of the following claims and their equivalents.

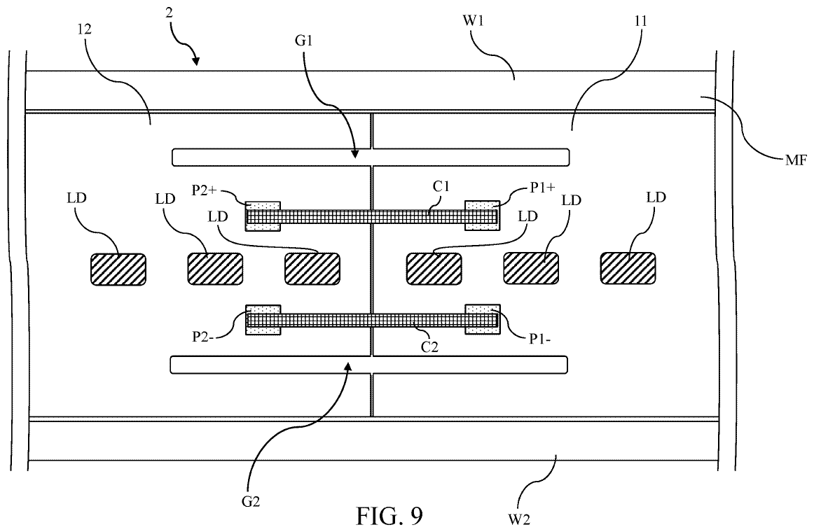

Please refer to FIG. 9, which is a ninth schematic view of the method for manufacturing high-reliability light source module in accordance with one embodiment of the present invention. As shown in FIG. 9, the other end of the second connector C2 is soldered on the negative solder pad P2− of the second sub-circuit board 12. Thus, the second groove G2 is located between the second connector C2 and the second side wall W2 of the section bar MF.

Via the aforementioned manufacturing method, a complete light source module 2 can be produced. Three or more sub-circuit boards can be spliced with each other by using the same method to increase the length of the light source board of the light source module 2. Subsequently, the installation procedure for the power module, light cover, and end caps can be carried out.

The aforementioned method does not require large equipment and can significantly reduce the manufacturing cost of light source boards of different lengths (such as 0.6 meters, 1.2 meters, 1.5 meters, 1.8 meters, 2.4 meters, etc.) through simple steps according to actual requirements. Therefore, the manufacturing cost of the lighting device can be greatly reduced in order to meet market demands.

As described above, the first connector C1 of the light source module 2 has the first bending region B1 with the first bending portions BP1 stacked together. The second connector C2 of the light source module 2 has the second bending region B2 with multiple second bending portions BP2 stacked together. Through the aforementioned structural design, the first bending region B1 and the second bending region B2 can act as buffer structures with a view to effectively preventing the occurrence of breakage of the first connector C1 and the second connector C2 due to external stress or thermal expansion and contraction during transportation. Therefore, the reliability of the light source module 2 can be greatly improved, such that the service life of the lighting device can be extended.

Additionally, the circuit board 1 of the light source module 2 has first groove G1 and second groove G2. The first groove G1 is located between the first connector C1 and the first side wall W1 of the section bar MF, while the second groove G2 is located between the second connector C2 and the second side wall W2 of the section bar MF. The aforementioned structural design can effectively increase the creepage distance between multiple solder pads of the light source module 2 and the section bar. Therefore, the quality of the light source module 2 can be effectively improved to meet the actual requirements.

The embodiment just exemplifies the present invention and is not intended to limit the scope of the present invention; any equivalent modification and variation according to the spirit of the present invention is to be also included within the scope of the following claims and their equivalents.

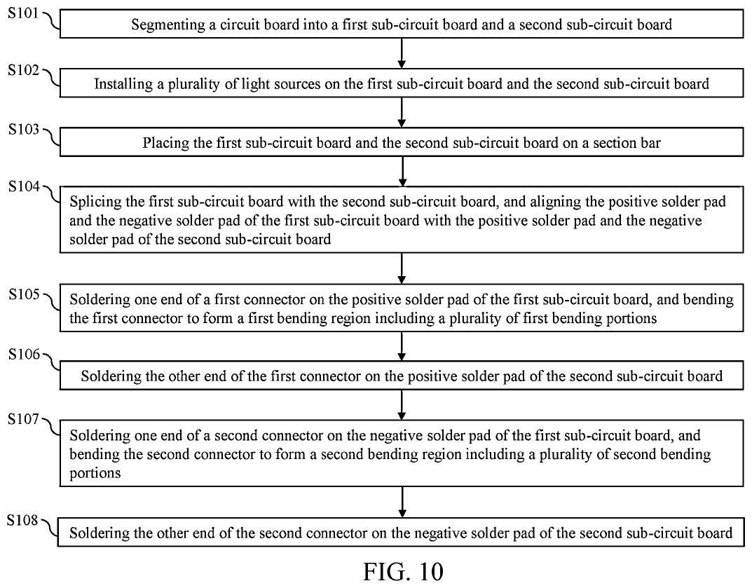

Please refer to FIG. 10, which is a flow chart of the method for manufacturing high-reliability light source module in accordance with one embodiment of the present invention. As shown in FIG. 10, the method for manufacturing high-reliability light source module of this embodiment includes the following steps:
Step S101: segmenting a circuit board into a first sub-circuit board and a second sub-circuit board.
Step S102: installing a plurality of light sources on the first sub-circuit board and the second sub-circuit board.
Step S103: placing the first sub-circuit board and the second sub-circuit board on a section bar.
Step S104: splicing the first sub-circuit board with the second sub-circuit board, and aligning the positive solder pad and the negative solder pad of the first sub-circuit board with the positive solder pad and the negative solder pad of the second sub-circuit board.
Step S105: soldering one end of a first connector on the positive solder pad of the first sub-circuit board, and bending the first connector to form a first bending region including a plurality of first bending portions.
Step S106: soldering the other end of the first connector on the positive solder pad of the second sub-circuit board.
Step S107: soldering one end of a second connector on the negative solder pad of the first sub-circuit board, and bending the second connector to form a second bending region including a plurality of second bending portions.
Step S108: soldering the other end of the second connector on the negative solder pad of the second sub-circuit board.

The embodiment just exemplifies the present invention and is not intended to limit the scope of the present invention; any equivalent modification and variation according to the spirit of the present invention is to be also included within the scope of the following claims and their equivalents.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

It is worthy to point out that the length of most of currently available light source board are limited to 0.6 meters, 1.2 meters, and 1.5 meters, requiring expensive large-scale equipment for customized manufacturing of 1.8 meters or 2.4 meters light source boards. Additionally, most suppliers are unable to manufacture light source boards of these lengths. As a result, the manufacturing cost of 1.8 meters or 2.4 meters light source boards is significantly increased, thereby raising the manufacturing cost of tube lights. By contrast, according to one embodiment of the present invention, the method for manufacturing high-reliability light source module includes the following steps: segmenting a circuit board into a first sub-circuit board and a second sub-circuit board; installing a plurality of light sources on the first sub-circuit board and the second sub-circuit board; placing the first sub-circuit board and the second sub-circuit board on a section bar; splicing the first sub-circuit board with the second sub-circuit board, and aligning the positive solder pad and the negative solder pad of the first sub-circuit board with the positive solder pad and the negative solder pad of the second sub-circuit board; soldering one end of a first connector on the positive solder pad of the first sub-circuit board; soldering the other end of the first connector on the positive solder pad of the second sub-circuit board; soldering one end of a second connector on the negative solder pad of the first sub-circuit board; and soldering the other end of the second connector on the negative solder pad of the second sub-circuit board. The aforementioned method enables the production of light source boards of different lengths (e.g., 0.6 meters, 1.2 meters, 1.5 meters, 1.8 meters, 2.4 meters, etc.) according to actual needs through simple steps without the need for large equipment. Thus, the method can significantly reduce the manufacturing cost of light source boards, such that the manufacturing cost of lighting devices can be greatly reduced to meet market demand.

Also, according to one embodiment of the present invention, the first connector of the light source module has a first bending region with a plurality of first bending portions, and the first bending portions are stacked together. The second connector of the light source module has a second bending region with a plurality of second bending portions, and the second bending portions are stacked together. Through the aforementioned structural design, the first bending region and the second bending region can serve as buffering structures so as to effectively prevent the occurrence of fracture of the first connector and the second connector due to external stress or thermal expansion and contraction during transportation. Therefore, the reliability of the light source module can be greatly improved, such that the service life of lighting devices can be extended.

Besides, according to one embodiment of the present invention, the first connector of the light source module has a first protrusion portion, while the second connector of the light source module has a second protrusion portion, with the top end of the first protrusion portion facing the top end of the second protrusion portion. Through the aforementioned structural design, the first protrusion portion and the second protrusion portion can also serve as buffering structures with a view to effectively preventing the occurrence of fracture of the first connector and the second connector due to external stress or thermal expansion and contraction during transportation. Therefore, the reliability of the light source module can be greatly improved, such that the service life of lighting devices can be further extended.

Moreover, according to one embodiment of the present invention, the circuit board of the light source module has a first groove and a second groove. The first groove is located between the first connector and the first side wall of the section bar, while the second groove is located between the second connector and the second side wall of the section bar. The aforementioned structural design can effectively increase the creepage distance between the solder pads of the light source module and the section bar. Therefore, the quality of the light source module can be effectively improved so as to meet actual requirements.

Furthermore, according to one embodiment of the present invention, the light sources of the light source module can be evenly distributed on the above sub-circuit boards. Therefore, through the aforementioned structural design, the light emitted by the light source module can be more uniform, thereby improving the overall efficiency of the lighting device. Consequently, the lighting device can provide users with a better user experience. As previous stated, the method for manufacturing high-reliability light source module according to the embodiments of the present invention can definitely achieve great technical effects.

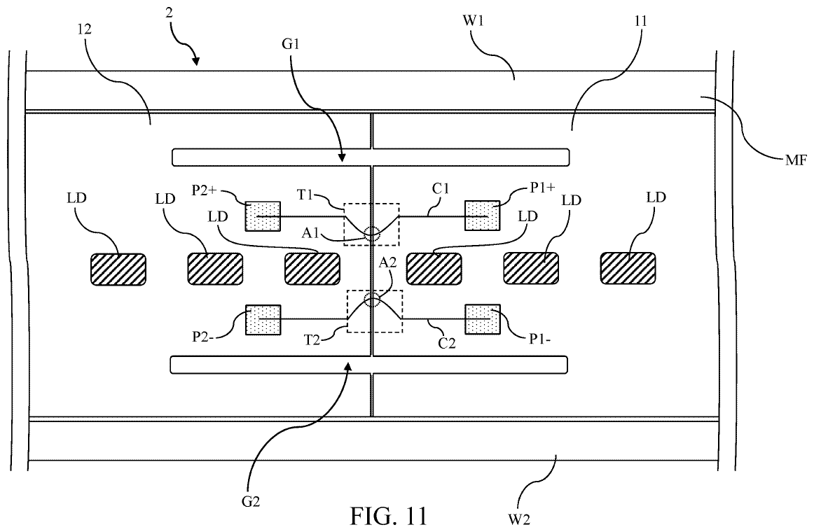

Please refer to FIG. 11, which is a schematic view of a method for manufacturing high-reliability light source module in accordance with another embodiment of the present invention. As shown in FIG. 11, the difference between this embodiment and the previous embodiment is that the structure of the first connector C1 and the second connector C2 are changed.

After completing the steps shown in FIG. 1˜FIG. 3, one end of the first connector C1 is soldered on the positive solder pad P1+ of the first sub-circuit board 11. Then, the first connector C1 is bent to form a first protrusion portion T1. The distance between the first protrusion portion T1 and the positive solder pad P1+ of the first sub-circuit board 11 is approximately equal to the distance between the first protrusion portion T1 and the positive solder pad P2+ of the second sub-circuit board 12. The first protrusion portion T1 can be triangular. In another embodiment, the first protrusion portion T1 can be semi-circular or of another shape; the shape of the first protrusion portion T1 can vary according to actual requirements. In this embodiment, the first connector C1 is a copper wire. Next, the other end of the first connector C1 is soldered on the positive solder pad P2+ of the second sub-circuit board 12.

Similarly, one end of the second connector C2 is soldered on the negative solder pad P1− of the first sub-circuit board 11. Then, the second connector C2 is bent to form a second protrusion portion T2; the top end A1 of the first protrusion portion T1 faces the top end A2 of the second protrusion portion T2. The distance between the second protrusion portion T2 and the negative solder pad P1− of the first sub-circuit board 11 is approximately equal to the distance between the second protrusion portion T2 and the negative solder pad P2− of the second sub-circuit board 12. The first protrusion portion T1 and the second protrusion portion T2 can be identical in shape. The second protrusion portion T2 can be triangular. In another embodiment, the second protrusion portion T2 can be semi-circular or of another shape; the shape of the second protrusion portion T2 can vary according to actual requirements. In this embodiment, the second connector C2 is a copper wire. Then, the other end of the second connector C2 is soldered on the negative solder pad P2− of the second sub-circuit board 12.

Through the above manufacturing method, a complete light source module 2 can be manufactured. By the same method, three or more sub-circuit boards can be interconnected to increase the length of the light source board of the light source module 2. Then, the installation process for the power module, light cover, and end caps can be carried out.

The above method for manufacturing the light source module does not require large equipment and can manufacture light source boards of different lengths (e.g., 0.6 meters, 1.2 meters, 1.5 meters, 1.8 meters, 2.4 meters, etc.) according to actual needs through simple steps, greatly reducing the manufacturing cost of the light source board. Therefore, the manufacturing cost of the lighting device can be greatly reduced to meet market demand.

As set forth above, the first connector C1 of the light source module 2 has the first protrusion portion T1, and the second connector C2 has the second protrusion portion T2; the top end A1 of the first protrusion portion T1 faces the top end A2 of the second protrusion portion T2. Through this structural design, the first protrusion portion T1 and the second protrusion portion T2 can also act as buffer structures, effectively preventing external stresses or thermal expansion and contraction during transportation, which could lead to the fracture of the first connector C1 and the second connector C2. Therefore, the reliability of the light source module 2 can be significantly improved in order to extend the service life of the lighting device.

Similarly, the circuit board 1 of the light source module 2 has the first groove G1 and the second groove G2. The first groove G1 is located between the first connector C1 and the first side wall W1 of the section bar MF, while the second groove G2 is located between the second connector C2 and the second side wall W2 of the section bar MF. This structural design effectively increases the creepage distance between the solder pads of the light source module 2 and the section bar, thereby effectively improving the quality of the light source module 2 to meet actual requirements.

In addition, the structural design where the top end A1 of the first protrusion portion T1 faces the top end A2 of the second protrusion portion T2 can extend the first protrusion portion T1 in a direction away from the first side wall W1 of the section bar MF and the second protrusion portion T2 in a direction away from the second side wall W2 of the section bar MF. Therefore, this structural design further enhances the creepage distance of the two components mentioned above. As a result, the quality of the light source module can be further improved to meet the requirements of practical applications.

The embodiment just exemplifies the present invention and is not intended to limit the scope of the present invention; any equivalent modification and variation according to the spirit of the present invention is to be also included within the scope of the following claims and their equivalents.

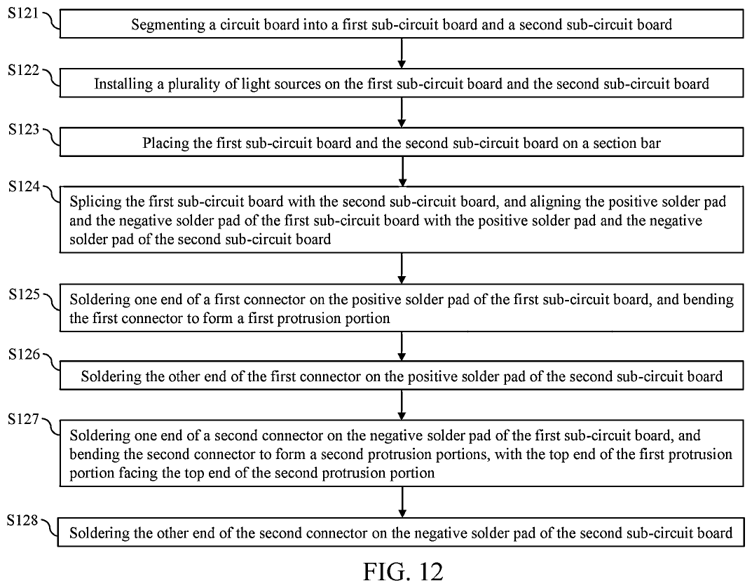

Please refer to FIG. 12, which is a flow chart of the method for manufacturing high-reliability light source module in accordance with another embodiment of the present invention. As shown in FIG. 12, As shown in FIG. 12, the method for manufacturing high-reliability light source module of this embodiment includes the following steps:
Step S121: segmenting a circuit board into a first sub-circuit board and a second sub-circuit board.
Step S122: installing a plurality of light sources on the first sub-circuit board and the second sub-circuit board.
Step S123: placing the first sub-circuit board and the second sub-circuit board on a section bar.
Step S124: splicing the first sub-circuit board with the second sub-circuit board, and aligning the positive solder pad and the negative solder pad of the first sub-circuit board with the positive solder pad and the negative solder pad of the second sub-circuit board.
Step S125: soldering one end of a first connector on the positive solder pad of the first sub-circuit board, and bending the first connector to form a first protrusion portion.
Step S126: soldering the other end of the first connector on the positive solder pad of the second sub-circuit board.
Step S127: soldering one end of a second connector on the negative solder pad of the first sub-circuit board, and bending the second connector to form a second protrusion portions, with the top end of the first protrusion portion facing the top end of the second protrusion portion.
Step S128: soldering the other end of the second connector on the negative solder pad of the second sub-circuit board.

The embodiment just exemplifies the present invention and is not intended to limit the scope of the present invention; any equivalent modification and variation according to the spirit of the present invention is to be also included within the scope of the following claims and their equivalents.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

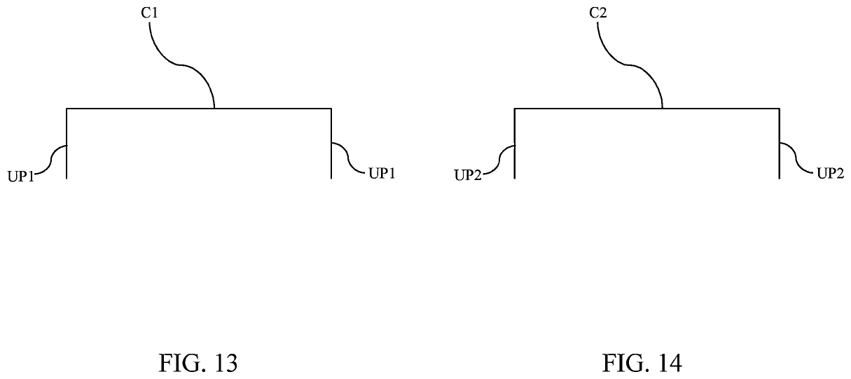

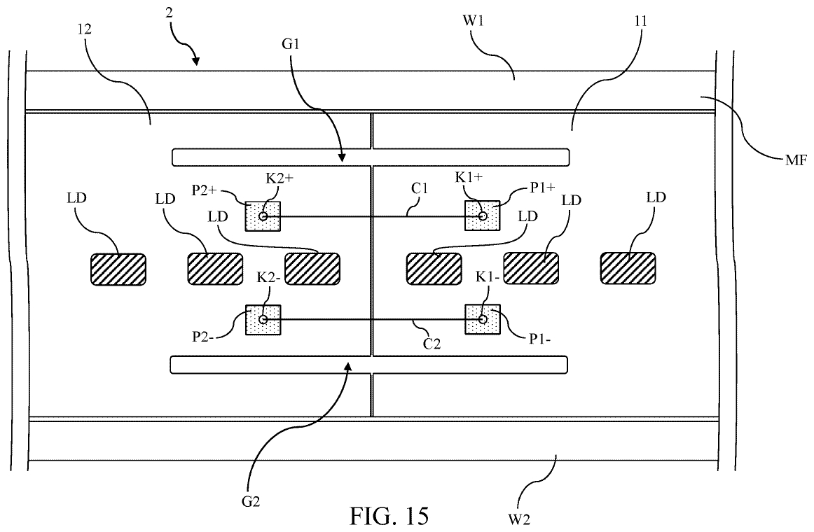

Please refer to FIG. 13, FIG. 14, and FIG. 15. FIG. 13 is a schematic view of a first connector in accordance with yet another embodiment of the present invention. FIG. 14 is a schematic view of a second connector in accordance with yet another embodiment of the present invention. FIG. 15 is a schematic view of a method for manufacturing high-reliability light source module in accordance with yet another embodiment of the present invention. As shown in

FIG. 13, FIG. 14, and FIG. 15, the structure of the first connector C1 and the second connector C2 in this embodiment differs from the previous embodiments.

Once steps 1 to 3 as shown in FIG. 1˜FIG. 3 are completed, the first connector C1 can be bent, forming two first connection pins UP1 at both ends of the first connector C1. Each first connection pin UP1 forms a 90-degree angle with the first connector C1. The positive solder pad P1+ of the first sub-circuit board 11 has a first positive solder pad hole K1+, while the positive solder pad P2+ of the second sub-circuit board 12 has a second positive solder pad hole K2+. The two first connection legs UP1 of the first connector C1 can be respectively inserted and soldered into the first positive solder pad hole K1+ and the second positive solder pad hole K2+, allowing the first connector C1 to connect the positive solder pads P1+ of the first sub-circuit board 11 and P2+ of the second sub-circuit board 12.

Similarly, the second connector C2 can be bent, forming two second connection pins UP2 at both ends of the second connector C2. Each second connection pin UP2 forms a 90-degree angle with the second connector C2. The negative solder pad P1− of the first sub-circuit board 11 has a first negative solder pad hole K1−, while the negative solder pad P2− of the second sub-circuit board 12 has a second negative solder pad hole K2−. The two second connection legs UP2 of the second connector C2 can be respectively inserted and soldered into the first negative solder pad hole K1− and the second negative solder pad hole K2−, allowing the second connector C2 to connect the negative solder pads P1− of the first sub-circuit board 11 and P2− of the second sub-circuit board 12.

Via the above manufacturing method, a complete light source module 2 can be manufactured. Using the same method, three or more sub-circuit boards can be spliced with each other to increase the length of the light source board of the light source module 2. Then, the installation process of the power module, light cover, and end caps can be carried out.

The above manufacturing method for the light source module does not require large equipment and can be used to manufacture light source boards of different lengths (such as 0.6 meters, 1.2 meters, 1.5 meters, 1.8 meters, 2.4 meters, etc.) according to actual needs, significantly reducing the manufacturing cost of the light source board. Therefore, the manufacturing cost of the lighting device can be greatly reduced to meet market demand.

The embodiment just exemplifies the present invention and is not intended to limit the scope of the present invention; any equivalent modification and variation according to the spirit of the present invention is to be also included within the scope of the following claims and their equivalents.

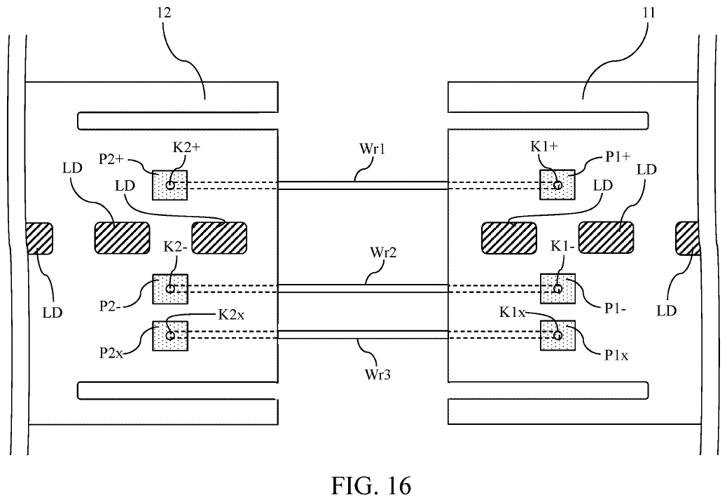

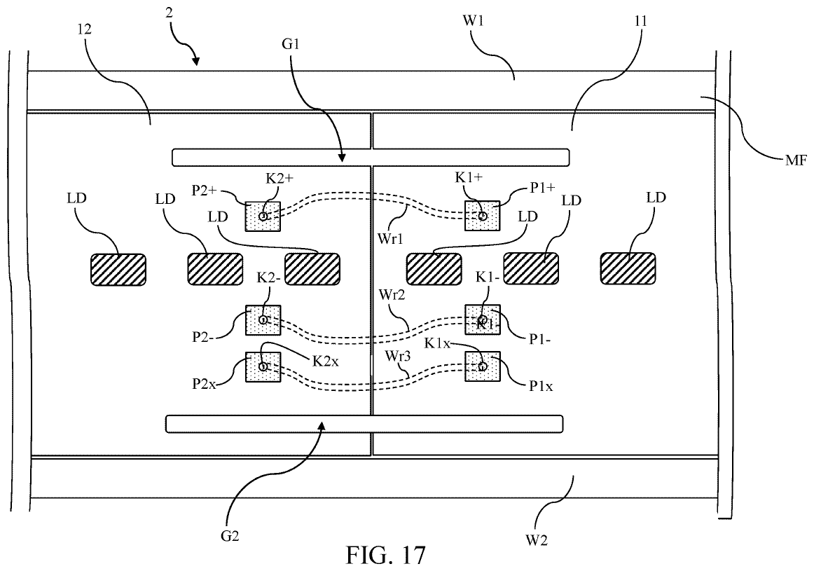

Please refer to FIG. 16 and FIG. 17. FIG. 16 is a first schematic view of a method for manufacturing high-reliability light source module in accordance with still another embodiment of the present invention. FIG. 17 is a second schematic view of a method for manufacturing high-reliability light source module in accordance with still another embodiment of the present invention. As shown in FIG. 16 and FIG. 17, the difference between this embodiment and the previous embodiments is that several silicone wires are used to replace the first connector C1 and the second connector C2. In addition, the first sub-circuit board 11 also includes solder pads P1x (the number of solder pads on the first sub-circuit board 11 exceeds two), while the second sub-circuit board 12 also includes solder pads P2x (the number of solder pads on the second sub-circuit board 12 exceeds two). The solder pad P1x has a solder pad hole K1x, while the solder pad P2x has a solder pad hole K2x.

Once steps 1 to 2 as shown in FIG. 1˜FIG. 2 are completed, one end of the first silicone wire Wr1 can be soldered on the first positive solder pad hole K1+ of the first sub-circuit board 11, and the other end of the first silicone wire Wr1 can be soldered on the second positive solder pad hole K2+ of the second sub-circuit board 12. Then, one end of the second silicone wire Wr2 can be soldered on the first negative solder pad hole K1-of the first sub-circuit board 11, and the other end of the second silicone wire Wr2 can be soldered on the second negative solder pad hole K2-of the second sub-circuit board 12. Similarly, one end of the third silicone wire Wr3 can be soldered on the solder pad hole K1x of the first sub-circuit board 11, and the other end of the third silicone wire Wr1 can be soldered on the solder pad hole K2x of the second sub-circuit board 12.

The first sub-circuit board 11 and the second sub-circuit board 12 are then placed on the section bar MF. Subsequently, the first sub-circuit board 11 and the second sub-circuit board 12 are spliced with each other, and the positive solder pads P1+ and negative solder pads P1− of the first sub-circuit board 11 are aligned with the positive solder pads P2+ and negative solder pads P2− of the second sub-circuit board 12 (the first sub-circuit board 11 and the second sub-circuit board 12 can be securely fastened to each other by riveting or similar methods). The positive solder pads P1+ and negative solder pads P1− of the first sub-circuit board 11 can be located between two light sources LD (where the two light sources LD are adjacent to each other, and one light source LD is adjacent to the second sub-circuit board 12). Similarly, the positive solder pads P2+ and negative solder pads P2− of the second sub-circuit board 12 can be located between two light sources LD (where the two light sources LD are adjacent to each other, and one light source LD is adjacent to the first sub-circuit board 11). In this way, the first sub-circuit board 11 and the second sub-circuit board 12 can form a complete light source board. The first silicone wire Wr1, the second silicone wire Wr2, and the third silicone wire Wr3 can then be placed between the section bar MF and the light source board to effectively utilize the space between the section bar MF and the light source board.

Via the above manufacturing method, a complete light source module 2 can be manufactured. Using the same method, three or more sub-circuit boards can be interconnected to increase the length of the light source board of the light source module 2. Then, the installation process of the power module, light cover, and end caps can be carried out.

Since the number of solder pads on the first sub-circuit board 11 and the second sub-circuit board 12 is three or more, short circuits are easily generated if the structure of the first connector C1 and the second connector C2 is used.

By contrast, since the first silicone wire Wr1, the second silicone wire Wr2, and the third silicone wire Wr3 are elastic and can be bent, they can be placed between the section bar MF and the light source board to prevent various problems caused by external stress or thermal expansion and contraction. The above structure not only effectively utilizes the space between the section bar MF and the light source board but also prevents short circuits. Additionally, the above structure can effectively reduce costs.

The embodiment just exemplifies the present invention and is not intended to limit the scope of the present invention; any equivalent modification and variation according to the spirit of the present invention is to be also included within the scope of the following claims and their equivalents.

To sum up, according to one embodiment of the present invention, the method for manufacturing high-reliability light source module includes the following steps: segmenting a circuit board into a first sub-circuit board and a second sub-circuit board; installing a plurality of light sources on the first sub-circuit board and the second sub-circuit board; placing the first sub-circuit board and the second sub-circuit board on a section bar; splicing the first sub-circuit board with the second sub-circuit board, and aligning the positive solder pad and the negative solder pad of the first sub-circuit board with the positive solder pad and the negative solder pad of the second sub-circuit board; soldering one end of a first connector on the positive solder pad of the first sub-circuit board; soldering the other end of the first connector on the positive solder pad of the second sub-circuit board; soldering one end of a second connector on the negative solder pad of the first sub-circuit board; and soldering the other end of the second connector on the negative solder pad of the second sub-circuit board. The aforementioned method enables the production of light source boards of different lengths (e.g., 0.6 meters, 1.2 meters, 1.5 meters, 1.8 meters, 2.4 meters, etc.) according to actual needs through simple steps without the need for large equipment. Thus, the method can significantly reduce the manufacturing cost of light source boards, such that the manufacturing cost of lighting devices can be greatly reduced to meet market demand.

Also, according to one embodiment of the present invention, the first connector of the light source module has a first bending region with a plurality of first bending portions, and the first bending portions are stacked together. The second connector of the light source module has a second bending region with a plurality of second bending portions, and the second bending portions are stacked together. Through the aforementioned structural design, the first bending region and the second bending region can serve as buffering structures so as to effectively prevent the occurrence of fracture of the first connector and the second connector due to external stress or thermal expansion and contraction during transportation. Therefore, the reliability of the light source module can be greatly improved, such that the service life of lighting devices can be extended.

Besides, according to one embodiment of the present invention, the first connector of the light source module has a first protrusion portion, while the second connector of the light source module has a second protrusion portion, with the top end of the first protrusion portion facing the top end of the second protrusion portion. Through the aforementioned structural design, the first protrusion portion and the second protrusion portion can also serve as buffering structures with a view to effectively preventing the occurrence of fracture of the first connector and the second connector due to external stress or thermal expansion and contraction during transportation. Therefore, the reliability of the light source module can be greatly improved, such that the service life of lighting devices can be further extended.

Moreover, according to one embodiment of the present invention, the circuit board of the light source module has a first groove and a second groove. The first groove is located between the first connector and the first side wall of the section bar, while the second groove is located between the second connector and the second side wall of the section bar. The aforementioned structural design can effectively increase the creepage distance between the solder pads of the light source module and the section bar. Therefore, the quality of the light source module can be effectively improved so as to meet actual requirements.

Furthermore, according to one embodiment of the present invention, the light sources of the light source module can be evenly distributed on the above sub-circuit boards. Therefore, through the aforementioned structural design, the light emitted by the light source module can be more uniform, thereby improving the overall efficiency of the lighting device. Consequently, the lighting device can provide users with a better user experience.

It will be apparent to those skilled in the art that various modifications and variations can be made to the disclosed embodiments. It is intended that the specification and examples be considered as exemplary only, with a true scope of the present invention being indicated by the following claims and their equivalents.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for manufacturing high-reliability light source module, comprising:
segmenting a circuit board into a first sub-circuit board and a second sub-circuit board;
installing a plurality of light sources on the first sub-circuit board and the second sub-circuit board;
placing the first sub-circuit board and the second sub-circuit board on a section bar;
splicing the first sub-circuit board with the second sub-circuit board, and aligning a positive solder pad and a negative solder pad of the first sub-circuit board with a positive solder pad and a negative solder pad of the second sub-circuit board;
soldering one end of a first connector on the positive solder pad of the first sub-circuit board;
soldering another end of the first connector on the positive solder pad of the second sub-circuit board;
soldering one end of a second connector on the negative solder pad of the first sub-circuit board; and
soldering another end of the second connector on the negative solder pad of the second sub-circuit board.

2. The method for manufacturing high-reliability light source module as claimed in claim 1, further comprising:
bending the first connector to form a first bending region comprising a plurality of first curved portions.

3. The method for manufacturing high-reliability light source module as claimed in claim 2, wherein the first curved portions are located above the positive solder pad of the first sub-circuit board or the positive solder pad of the second sub-circuit board.

4. The method for manufacturing high-reliability light source module as claimed in claim 1, further comprising:
bending the second connector to form a second bending region comprising a plurality of second curved portions.

5. The method for manufacturing high-reliability light source module as claimed in claim 4, wherein the second curved portions are located above the negative solder pad of the first sub-circuit board or the negative solder pad of the second sub-circuit board.

6. The method for manufacturing high-reliability light source module as claimed in claim 1, further comprising:
bending the first connector to form a first protrusion portion; and
bending the second connector to form a second protrusion portion, wherein a top end of the first protrusion portion faces a top end of the second protrusion portion.

7. The method for manufacturing high-reliability light source module as claimed in claim 1, further comprising:
cutting the circuit board to form a first groove and a second groove.

8. The method for manufacturing high-reliability light source module as claimed in claim 7, wherein the first groove is located between the first connector and a first side wall of the section bar.

9. The method for manufacturing high-reliability light source module as claimed in claim 7, wherein the second groove is located between the second connector and a second side wall of the section bar.

10. The method for manufacturing high-reliability light source module as claimed in claim 1, wherein the first connector and the second connector are solder strips, solder bars, or copper wires.
